(19) United States
(12) Patent Application Publication
(10) Pub. No.: US 2017/0090258 A1
(43) Pub. Date: Mar. 30, 2017

(54) PIXEL STRUCTURE AND DISPLAY PANEL HAVING THE SAME

(71) Applicant: SHENZHEN CHINA STAR OPTOELECTRONICS TECHNOLOGY CO., LTD., Shenzhen, Guangdong (CN)

(72) Inventor: Li CHAI, Shenzhen, Guangdong (CN)

(21) Appl. No.: 14/416,316

(22) PCT Filed: Jul. 14, 2014
(86) PCT No.: PCT/CN2014/082173

§ 371 Date: Jan. 22, 2015

(30) Foreign Application Priority Data
Jun. 18, 2014 (CN) 201410274040.5

(51) Int. Cl. G02F 1/1362; G02F 1/1368

(52) U.S. Cl. CPC G02F 1/136286; G02F 1/1368; G02F 1/136213; G02F 1/13624; G02F 2201/123; H01L 29/78696

(57) ABSTRACT

The present disclosure discloses a pixel structure and a display panel having the same. The pixel structure comprises a plurality of sub-pixels each having a first display area configured to receive a scan signal from a scan line and then a data signal from a data line, so as to possess a first electric potential, and a second display area configured to receive the scan signal from the scan line and then the data signal from the data line, and to receive a voltage signal from a common line, so as to pull the voltage obtained based on the data signal from the data line down to a second electric potential, which is different from the first electrical potential. The pixel structure can achieve a wide viewing angle without sacrificing the aperture ratio and can reduce chances of short circuits between scan lines and data lies.

The present application claims benefit of Chinese patent application CN 201410274040.5, entitled “Pixel structure and display panel having the same” and filed on Jun. 18, 2014, the entirety of which is incorporated herein by reference.

### FIELD OF THE INVENTION

The present disclosure relates to the field of liquid crystal displays, in particular to a pixel structure and a display panel having the same.

### BACKGROUND OF THE INVENTION

The development of information society increases the demanding for display devices and therefore promotes rapid growth of the industry of liquid crystal displays. As display sizes of liquid display panels are increasingly larger, technologies of wide viewing angle for liquid display panels require improvement and breakthrough to overcome viewing angle defects for large size display.

An existing wide viewing angle design in the field divides one pixel area into a main pixel area and a secondary-pixel area, so that the voltage in the secondary-pixel area can be pulled down via a sharing thin film transistor (TFT for short) and a pull-down capacitor. Therefore, a difference is generated between the liquid crystal rotation amounts in the main pixel area and in the secondary-pixel area, thus obtaining a wide viewing angle.

The inventor of the present disclosure has discovered existence of at least the following technical defects in the prior art in achieving the present disclosure. In the afore-mentioned design, the sharing TFT is generally driven by a scan line in the secondary-pixel area. This being the case, the scan line in the secondary-pixel area of pixel area N will be connected to the scan line in the main pixel area of pixel area N+1, N+2, N+3, or N+4, thus not only greatly affecting the aperture ratio, but also enlarging the overlapping areas between the scan line, data line, and a first metal layer. As a result, short circuits between the scan line and the data line would be more likely to happen, thus largely adding costs of a product.

Consequently, a new pixel structure is in urgent need to achieve a wide viewing angle without sacrificing the aperture ratio and to reduce chances of a short circuit between the scan line and data line.

### SUMMARY OF THE INVENTION

According to one aspect of the present disclosure, it aims to provide a pixel structure, which can achieve a wide viewing angle without sacrificing the aperture ratio and can reduce chances of short circuits between scan lines and data lines. The present disclosure further provides a display panel.

(1) In order to solve the above technical problems, the present disclosure provides a pixel structure, comprising a plurality of sub-pixels each having a first display area configured to receive a scan signal from a scan line and then a data signal from a data line, so as to possess a first electric potential, and a second display area configured to receive the scan signal from the scan line and then the data signal from the data line, and to receive a voltage signal from a common line, so as to pull the voltage obtained based on the data signal from the data line down to a second electric potential, a voltage difference existing between the first and the second electrical potentials.

(2) In one preferred embodiment of item (1) of the present disclosure, the first display area comprises a first switch element, and the second display area comprises a second switch element, a sharing switch element, and a pull-down capacitor, each switch element having a gate, a source, and a drain. The first switch element and the second switch element have their gates both connected to the scan line, their sources both connected to the data line, and their drains connected to a first sub-pixel electrode of the first display area and a second sub-pixel electrode of the second display area, respectively. The sharing switch element has its gate connected to the common line, its source connected to the second sub-pixel electrode of the second display area, and its drain connected to one end of the pull-down capacitor, the other end of which is connected to the common line.

(3) In one preferred embodiment according to item (1) or (2) of the present disclosure, the switch element is in the form of a thin film transistor.

(4) In one preferred embodiment according to any one of items (1) to (3) of the present disclosure, the channel of the second switch element and the channel of the sharing switch element have the same width-length ratio.

(5) According to another aspect of the present disclosure, it provides a display panel, comprising: a plurality of data lines, a plurality of scan lines perpendicularly staggered with the data lines to form a plurality of secondary-pixel areas, and a plurality of sub-pixels arranged in the secondary-pixel areas. The plurality of sub-pixels each include a first display area configured to receive a scan signal from a scan line, and then a data signal from a data line, so as to possess a first electric potential, and a second display area configured to receive the scan signal from the scan line and then the data signal from the data line, and to receive a voltage signal from a common line, so as to pull the voltage obtained based on the data signal from the data line down to a second electric potential, a voltage difference existing between the first and second electrical potentials.

(6) In one preferred embodiment according to item (5) of the present disclosure, the first display area comprises a first switch element, and the second display area comprises a second switch element, a sharing switch element, and a pull-down capacitor, each switch element having a gate, a source, and a drain. The first switch element and the second switch element have their gates both connected to the scan line, their sources both connected to the data line, and their drains connected to a first sub-pixel electrode of the first display area and a second sub-pixel electrode of the second display area, respectively. The sharing switch element has its gate connected to the common line, its source connected to the second sub-pixel electrode of the second display area, and its drain connected to one end of the pull-down capacitor, the other end of which is connected to the common line.

(7) In one preferred embodiment according to item (5) or (6) of the present disclosure, the switch element is in the form of a thin film transistor.

(8) In one preferred embodiment according to any one of items (5) to (7) of the present disclosure, the channel of the second switch element and the channel of the sharing switch element have the same width-length ratio.

Compared to the prior art, one or a plurality of the above embodiments may have the following advantages or beneficial effects.

According to the embodiments of the present disclosure, the constant voltage on the common line of an array substrate is used to turn on the sharing switch element in the second pixel area, so as to pull down the voltage in the second pixel area with the pull-down capacitor while the pixel electrode of the second pixel area is being sufficiently charged, thus achieving the effect of a low color shift. In addition, according to the embodiments of the present disclosure, it enables a higher aperture ratio and reduces chances of short circuits between the scan line and the data line by removing the scan line in the secondary-pixel area of each sub-pixel as used in the prior art, thus saving both energy and costs.

Other features and advantages of the present disclosure will be illustrated and become partially obvious in the following description, and be understood through implementation of the present disclosure. The purposes and other advantages of the present disclosure will be achievable or obtainable through the structures as indicated in the following description, claims, and drawings.

### BRIEF DESCRIPTION OF THE DRAWINGS

The drawings are provided for further understanding of the present disclosure, and constitute one part of the description. They serve to explain the present disclosure in conjunction with the embodiments, rather than to limit the present disclosure in any manner. In the drawings:

FIG. 1 is the structural diagram of a sub-pixel in the prior art;

FIG. 2 is an equivalent circuit of the sub-pixel as shown in FIG. 1;

FIG. 3 schematically shows the structure of a display panel according to an embodiment of the present disclosure;

FIG. 4 schematically shows the structure of a sub-pixel according to an embodiment of the present disclosure; and

FIG. 5 is an equivalent circuit of the sub-pixel as shown in FIG. 4.

### DETAILED DESCRIPTION OF THE EMBODIMENTS

The present disclosure will be explained by reference to the following detailed description of embodiments taken in connection with the accompanying drawings, whereby it can be readily understood how to solve the technical problem by the technical means according to the present disclosure and achieve the technical effects thereof, and thus the technical solution according to the present disclosure can be implemented. It is important to note that as long as there is no conflict, combinations of the above-described embodiments and of technical features therein are possible, and technical solutions obtained in this manner are intended to be within the scope of the present disclosure.

The following embodiments are explained with reference to the accompanying drawings, which specifically illustrate implementable embodiments of the present disclosure. Spatial references in the present disclosure, such as “upper”, “lower”, “left”, and “right” indicate respective directions relative to the accompanying drawings. Hence, they are for illustrative purposes only and are not intended to be limiting of the claimed disclosure.

Moreover, for the sake of clarity, the size and thickness of each element indicated in the drawings are not subject to any proportionality to limit the present disclosure.

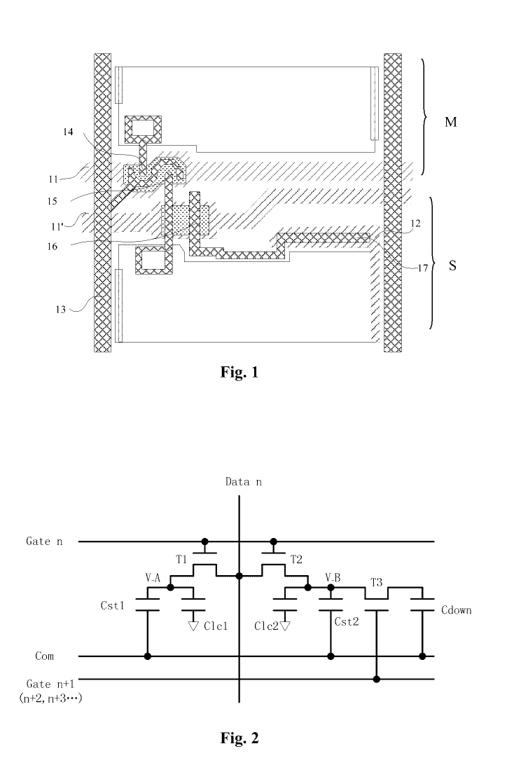

FIG. 1 is the structural diagram of a sub-pixel in the prior art. As shown in FIG. 1, the sub-pixel is divided into two areas, i.e., a main pixel area M and a secondary pixel area S. The sub-pixel includes a main pixel area scan line 11, a secondary-pixel area scan line 11′, a common line 12, a scan line 13, a main pixel area switch element 14, a secondary-pixel area switch element 15, a sharing switch element 16, and a pull-down capacitor 17. In such a structure, when the secondary-pixel area switch element 15 is switched on, the voltage in the secondary-pixel area S can be pulled down via the sharing switch element 16 and the pull-down capacitor 17, so as to generate different liquid crystal rotation amounts between the main pixel area M and the secondary-pixel area S. As a result, a wide viewing angle can be obtained.

FIG. 2 is an equivalent circuit of the sub-pixel as shown in FIG. 1. As indicated in FIG. 2, a main pixel area switch element T1 and a secondary-pixel area switch element T2 have their gates both connected to a scan line Gate n, and their sources both connected to a data line Data n. A sharing switch element T3 has its source connected to the drain of the secondary-pixel area switch element T2, its drain connected to a pull-down capacitor Cdown, and its gate connected to a scan line Gate n+1 (Gate n+2, or Gate n+3, etc.). When a turn-on voltage is input into the scan line Gate n, the switch elements T1 and T2 are simultaneously turned on, so that the main pixel area M and secondary-pixel area S receive a data signal from the data line Data n to possess a first electric potential. When the charging step is finished, the voltage of the main pixel area M, i.e., V_A is the same as that of the secondary-pixel area S, i.e., V_B. When a turn-on voltage is input into the scan line Gate n+1, the switch element T3 is turned on, so that voltage V_B in the secondary-pixel area S can be pulled down via the pull-down capacitor Cdown. Hence, a voltage difference can be generated between voltage V_B in the secondary-pixel area S and voltage V_A in the main pixel area M, thus achieving the effect of a low color shift.

It can be easily understood that the above design in the prior art not only sacrifices the aperture ratio, but also doubles the number of scan lines, thus greatly increasing the risk of short circuits between data lines and scan lines.

The embodiments of the present disclosure provide solutions to the above problems, and will be explained in the following with reference to the drawings.

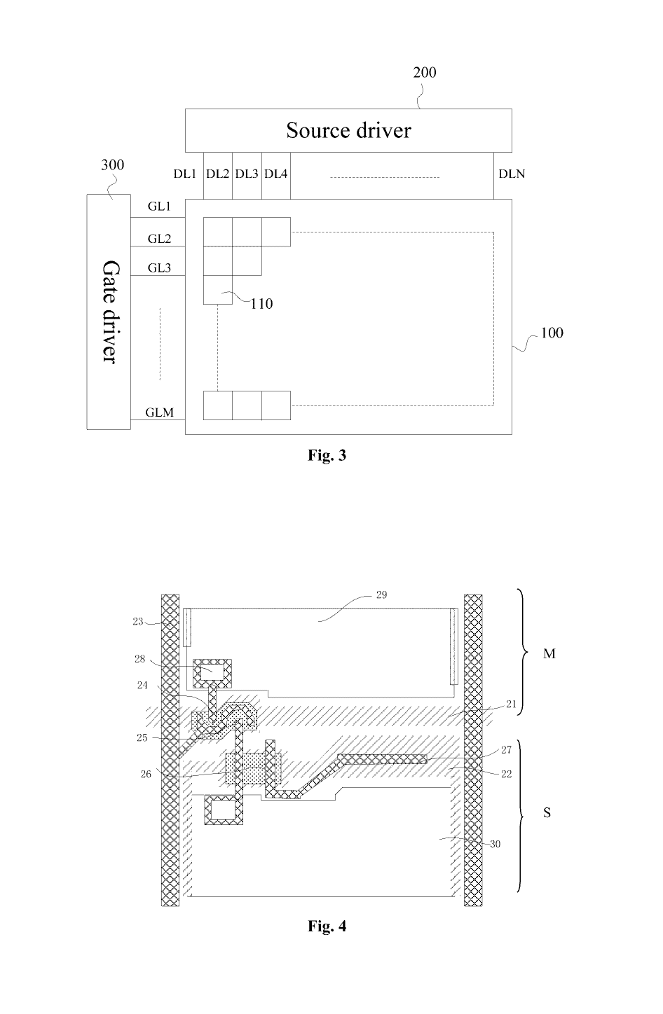

FIG. 3 schematically shows the structure of a display panel according to an embodiment of the present disclosure. The display panel includes an image display area 100, a source driver 200, and a gate driver 300. The image display area 100 has an array and a plurality of pixel structures 110 formed by a plurality of data lines (N data lines DL1 to DLN as shown in FIG. 3) perpendicularly staggered with a plurality of scan lines (M scan lines GL1 to GLM as shown in FIG. 3). The source driver 200, via a plurality of data lines coupled therewith, transmits supplied data signals to the image display area 100. And the gate driver 300, via a plurality of scan lines coupled therewith, transmits supplied scan signals to the image display area 100.

It should be noted that the term “pixel structure” of the present disclosure comprises a plurality of sub-pixels that are each arranged in one of a plurality of secondary-pixel areas formed by the plurality of data lines perpendicularly staggered with the plurality of scan lines. In the embodiment as shown in FIG. 3, the sub-pixels can be of different colors, such as red, green, and blue ones.

FIG. 4 schematically shows the structure of a sub-pixel according to an embodiment of the present disclosure. The sub-pixel can be used in the display panel as indicated in FIG. 3.

As illustrated in FIG. 4, the sub-pixel includes a first display area M (hereinafter referred as the area M) and a second display area S (hereinafter referred as the area S). The area M can be configured to receive a scan signal from a scan line 21, and then a data signal from a data line 23, so as to possess a first electric potential. And the area S can be configured to receive the scan signal from the scan line 21, and then the data signal from the data line 23. The area S can be further configured to receive a voltage signal from a common line 22, and pull down a voltage obtained based on the data signal from the data line 23 to a second electric potential, which is different from the first electric potential.

As shown in FIG. 4, the area M comprises a main pixel area pixel electrode 29 and a first switch element 24 that are connected to each other via a via hole 28. The area S comprises a secondary-pixel area pixel electrode 30, a second switch element 25, a sharing switch element 26, and a pull-down capacitor 27, wherein the pixel electrode 30 is connected to the second switch element 25 via a via hole. The scan line 21 can be used to control turn-on of the first switch element 24 and the second switch element 25. The common line 22 can be used to control turn-on of the sharing switch element 26, so as to charge the pull-down capacitor 27 via the sharing switch element 26. The pixel electrodes 29 and 30 can be preferably both transparent pixel electrodes made of ITO materials.

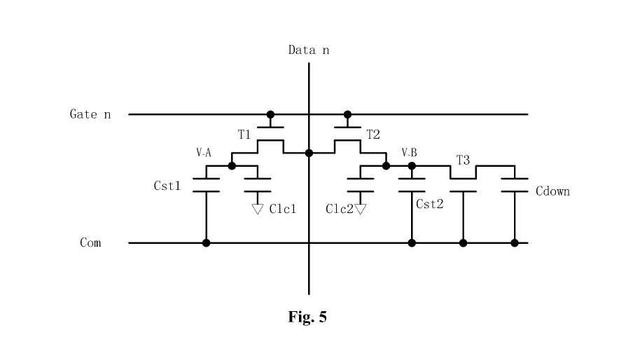

The structure of the sub-pixel will be illustrated with reference to FIG. 4 and FIG. 5, which is an equivalent circuit of the sub-pixel as shown in FIG. 4. The sub-pixel includes switch elements T1, T2, and T3, storage capacitors Cst1 and Cst2, and liquid crystal capacitors Clc1 and Clc2. The switch elements T1, T2, and T3 each can be preferably made of thin film transistor.

It should be noted that a common line Com as shown in FIG. 5 is located on an array substrate. Although the voltage (generally about 6 V) on the common line Com is smaller than the voltage (generally in the range from 27 V to 33 V) normally exerted on the scan line for turning on the switch element, the constant voltage on the common line Com can turn on the switch element also.

In the area M (see the left side of FIG. 5), the first switch element T1 has its source connected to the data line Date n, its drain connected to a sub-pixel electrode V_A, and its control terminal (gate) connected to the scan line Gate n. The storage capacitor Cst1 can be connected between the sub-pixel electrode V_A and the common line Com, and the crystal capacitor Clc1 can be connected between the sub-pixel electrode V_A and another common line (generally located on a color filter substrate). When the first switch element is turned on, a data signal from the data line Data n is transmitted to the storage capacitor Cst1 via the first switch element T1, while the storage capacitor Cst1 can be charged according to the data signal to store a corresponding electric potential. On the above basis, the sub-pixel electrode V_A also possesses a corresponding electric potential. The area M thus displays image data.

In the area S (see the right side of FIG. 5), the second switch element T2 has its source connected to the data line Date n, its drain connected to a sub-pixel electrode V_B, and its control terminal (gate) connected to the scan line Gate n. The storage capacitor Cst2 can be connected between the sub-pixel electrode V_B and the common line Com, and the crystal capacitor Clc2 can be connected between the sub-pixel electrode V_B and another common line. When the second switch element T2 is turned on, the data signal from the data line Data n is transmitted to the storage capacitor Cst2 via the second switch element T2, while the storage capacitor Cst2 can be charged according to the data signal to store a corresponding first electric potential. The sub-pixel electrode V_B also possesses a corresponding first electric potential.

It should be particularly noted that when the area S is being charged, the voltage of the common line Com enables turn-on of the sharing switch element T3, so that the pull-down capacitor Cdown can be simultaneously charged. Hence, the pull-down capacitor Cdown can also be used to pull down the voltage in the area S, so as to generate a voltage difference between the voltage in the area S and that in the area M, thus achieving the effect of a low color shift.

In addition, it should be noted that the voltage of the common line on the array substrate is generally constant (at about 6 V). According to existing I-V curves of non-crystalline silicon, a turn-on voltage of 6 V and a turn-on voltage in the range from 27 V to 33 V have an on-state current ratio of 1:10. Besides, on-state currents are closely associated with the charging rate of the pixel electrode. That is, when certain electric charge is to be charged to a pixel electrode, a larger on-state current indicates a larger charging rate to the pixel electrode, while a smaller on-state current suggests a smaller charging rate to the pixel electrode.

In view of the above, when a normal turn-on voltage (for example 33 V) is exerted on the scan line Gate n so that the first switch element T1 in the area M and the second switch element T2 in the area S are respectively turned on to charge the areas M and S, the sharing switch element T3 can be simultaneously turned on owning to the constant voltage (for example 6 V) on the common line. As a result, the pull-down capacitor Cdown is also simultaneously charged. However, due to different on-state currents, during a period when one corresponding scan line is being turned on, the pull-down capacitor Cdown can only be charged 10% of its charge capacity. That is, when the scan line Gate n is turned off, about 90% of the charge capacity of the pull-down capacitor Cdown is not charged. Hence, if the pull-down capacitor Cdown is to be sufficiently charged, a time period for turning on 10 corresponding scan lines will be required.

As a driving signal is scanning the scan lines from scan line N+1 to scan line N+9, the sharing switch element T3 corresponding to scan line N is constantly charging the pull-down capacitor Cdown, which meanwhile pulls down the voltage of the pixel electrode in the area S. When the pull-down capacitor Cdown is in charge saturation, although the sharing switch element T3 is kept on, it will not be able to pull down the voltage of the pixel electrode in the area S. Thus, when the driving signal begins to scan the scan line N+10, the voltages of the areas M and S corresponding to scan line N are both stable (in case off-state current leakage is ignored), and a certain voltage difference is kept between the voltages of the areas M and N, thus achieving a low color shift.

It should be noted that the channel of the sharing switch element T3 and the channel of the second switch element T2 have the same width-length ratio. The width-length ratios of the channel of the sharing switch element T3 and the channel of the second switch element T2 certainly can be re-selected according to actual requirements to achieve the above effects of the embodiment, which will not be repeated here.

To conclude the above, according to the embodiments of the present disclosure, the constant voltage of the common line on the array substrate is used to turn on the sharing switch element in the second pixel area, so that when the pixel electrode in the second pixel area is being sufficiently charged, the voltage of the second pixel area can still be pulled down with a pull-down capacitor, thus achieving the effect of a low color shift. Furthermore, according to the embodiments of the present disclosure, the scan line in the secondary-pixel area of each sub-pixel as used in the prior art can be removed. As a result, the aperture ratio can be improved and the chances of short circuits between the scan line and the data line can be reduced, thus saving both energy and costs.

The above description should not be construed as limitations of the present disclosure, but merely as exemplifications of preferred embodiments thereof Δny variations or replacements that can be readily envisioned by those skilled in the art are intended to be within the scope of the present disclosure. Hence, the scope of the present disclosure should be subjected to the scope defined in the claims.

1. A pixel structure, comprising a plurality of sub-pixels each having:
a first display area configured to receive a scan signal from a scan line and then a data signal from a data line, so as to possess a first electric potential, and
a second display area configured to receive the scan signal from the scan line and then the data signal from the data line, and to receive a voltage signal from a common line, so as to pull the voltage obtained based on the data signal from the data line down to a second electric potential, a voltage difference existing between the first and second electrical potentials.

2. The pixel structure of claim 1, wherein the first display area comprises a first switch element, and the second display area comprises a second switch element, a sharing switch element, and a pull-down capacitor, each switch element having a gate, a source, and a drain,
wherein the first switch element and the second switch element have their gates both connected to the scan line, their sources both connected to the data line, and their drains connected to a first sub-pixel electrode of the first display area and a second sub-pixel electrode of the second display area, respectively; and
wherein the sharing switch element has its gate connected to the common line, its source connected to the second sub-pixel electrode of the second display area, and its drain connected to one end of the pull-down capacitor, the other end of which is connected to the common line.

3. The pixel structure of claim 2, wherein the switch element is in the form of a thin film transistor.

4. The pixel structure of claim 3, wherein the channel of the second switch element and the channel of the sharing switch element have the same width-length ratio.

5. A display panel comprising:
a plurality of data lines,
a plurality of scan lines perpendicularly staggered with the data lines to form a plurality of secondary-pixel areas, and
a plurality of sub-pixels arranged in the secondary-pixel areas, the plurality of sub-pixels each including:
a first display area configured to receive a scan signal from a scan line, and then a data signal from a data line, so as to possess a first electric potential, and
a second display area configured to receive the scan signal from the scan line and then the data signal from the data line, and to receive a voltage signal from a common line, so as to pull the voltage obtained based on the data signal from the data line down to a second electric potential, a voltage difference existing between the first and second electrical potentials.

6. The display panel of claim 5, wherein the first display area comprises a first switch element, and the second display area comprises a second switch element, a sharing switch element, and a pull-down capacitor, each switch element having a gate, a source, and a drain,
wherein the first switch element and the second switch element have their gates both connected to the scan line, their sources both connected to the data line, and their drains connected to a first sub-pixel electrode of the first display area and a second sub-pixel electrode of the second display area, respectively; and
wherein the sharing switch element has its gate connected to the common line, its source connected to the second sub-pixel electrode of the second display area, and its drain connected to one end of the pull-down capacitor, the other end of which is connected to the common line.

7. The display panel of claim 6, wherein the switch element is in the form of a thin film transistor.

8. The display panel of claim 7, wherein the channel of the second switch element and the channel of the sharing switch element have the same width-length ratio.
